(19) United States
(12) Patent Application Publication
(10) Pub. No.: US 2007/0269338 A1
(43) Pub. Date: Nov. 22, 2007

(54) Silicon Epitaxial Wafer and Manufacturing Method Thereof

(75) Inventors: Fumitaka Kume, Gunma (JP); Tomosuke Yoshida, Gunma (JP); Ken Aihara, Gunma (JP); Ryoji Hoshi, Fukushima (JP); Satoshi Tobe, Gunma (JP); Naohisa Toda, Gunma (JP); Fumio Tahara, Gunma (JP)

Correspondence Address: SNIDER & ASSOCIATES, P. O. BOX 27613, WASHINGTON, DC, 20038-7613, US

(73) Assignee: Shin-Etsu Handotai Co., Ltd, Tokyo (JP)

(21) Appl. No.: 11/632,720

(22) PCT Filed: Jun. 27, 2005
(86) PCT No.: PCT/JP05/11749

§ 371 Date: Jan. 18, 2007

(30) Foreign Application Priority Data
Jul. 20, 2004 (JP) 2004-212165

(51) Int. Cl. C30B 15/00; C22C 29/00; C30B 15/14

(52) U.S. Cl. 420/578; 117/19; 117/3

(57) ABSTRACT

A silicon epitaxial wafer 100 is formed by growing a silicon epitaxial layer 2 on a silicon single crystal substrate 1, produced by means of a CZ method, and doped with boron so that a resistivity thereof is less than 0.018 Ω·cm. The silicon single crystal substrate 1 has a density of bulk stacking faults 13 in the silicon single crystal substrate 1 in the range of 1×10⁸ cm⁻³ or higher and 3×10⁹ cm⁻³ or lower. Thereby, provided is a silicon epitaxial wafer having a boron doped p⁺ CZ substrate with a resistivity of 0.018Ω·cm or lower, and a state of formation of oxygen precipitates can be adjusted adequately so as to secure a sufficient IG effect and to suppress a problem of bow and deformation of a substrate, despite that sizes of oxygen precipitates is so small to be observed accurately.

### BACKGROUND OF THE INVENTION

1. Field of this Invention

This invention relates to a silicon epitaxial wafer obtained by vapor phase growing of a silicon epitaxial layer on a silicon single crystal substrate to which boron is added at a comparatively high concentration, and to a manufacturing method thereof.

2. Description of the Related Art

A silicon epitaxial wafer obtained by vapor phase growing of a silicon epitaxial layer on a silicon single crystal substrate (hereinafter referred to as p⁺CZ substrate) produced by means of a Czochralski method (hereinafter referred to simply as CZ method) and having boron added at a comparatively high concentration, so that a resistivity thereof is 0.018Ω·cm or less, has been widely employed for, for example, latch-up prevention or formation of a defect free device forming region.

Many of oxygen precipitation nuclei are formed in a p⁺ CZ substrate during cooling to room temperature after solidification as crystal in a crystal pulling step. A size of an oxygen precipitation nucleus is very small and usually 1 nm or less. A precipitation nucleus grows to an oxygen precipitate if the precipitation nucleus is held at a temperature in the range of a nucleus formation temperature or higher and a critical temperature of re-solid solution in a silicon single crystal bulk or less. The oxygen precipitate is one kind of crystal defects referred to BMD (Bulk Micro Defect) and works as an adverse factor such as lowering in withstand voltage or current leakage; therefore, it is desired that an oxygen precipitate is formed in a device formation region at the lowest possible level. In a substrate region that is not used for device formation, however, the oxygen precipitates can be effectively used as getters for heavy metal components in a device fabrication process; therefore, in a case of a silicon epitaxial wafer as well, oxygen precipitates have been intentionally formed in a silicon single crystal substrate for the growth thereof at a concentration in the range where no problem such as bow occurs. A gettering effect acting on heavy metals by such an oxygen precipitate is one of so called IG (Intrinsic Gettering) effects.

It has been known that a precipitation nucleus of an oxygen precipitate, being retained higher than the above critical temperature, is annihilated by re-solid solution in a silicon single crystal bulk. Since a silicon epitaxial wafer is manufactured with a vapor phase growth step for a silicon epitaxial layer, which is a high temperature annealing of 1100° C. or higher, at which nucleus annihilation occurs, many of existing oxygen precipitation nuclei prior to vapor phase growth are annihilated in the course of a thermal history of the vapor phase growth. With fewer precipitation nuclei, formation of oxygen precipitates is suppressed in a semiconductor device fabrication process even if an initial oxygen concentration of an applied silicon single crystal is high, and thus an IG effect can not be expected much.

In order to solve this problem, a method has been proposed in which oxygen precipitation nuclei are newly produced in a p⁺ CZ substrate by applying low temperature annealing at a temperature in the range of 450° C. or higher and 750° C. or lower to a silicon epitaxial wafer and thereafter, medium temperature annealing (in the range between low temperature annealing and high temperature annealing) is applied to thereby grow oxygen precipitates (JP-A Nos. 9-283529 and 10-270455, and WO 01/056071). Another method has been proposed in JP-A No. 9-283529 in which oxygen precipitation nuclei or oxygen precipitates are formed in a p⁺ CZ substrate and thereafter, a silicon epitaxial layer is grown in a vapor phase so as to manufacture a silicon epitaxial wafer.

A boron doped p+ CZ substrate has a tendency that with a lower substrate resistivity (that is, with a higher boron concentration), a density of formation of oxygen precipitation nuclei increases, resulting in a higher density of oxygen precipitates, after the medium temperature annealing, which is disclosed in JP-A Nos. 9-283529 and 10-270455 and WO 01/056071. This is considered because a great amount of boron (dopant) added into a p⁺ CZ substrate is changed into negative ions in a silicon bulk, which bond to interstitial silicon atoms with positive charge preventing oxygen precipitation, so as to suppress the migration thereof.

From the viewpoint of the IG effect mentioned above, it has been generally accepted that a higher density of formation of oxygen precipitates is more advantageous. It has been understood, however, that an IG effect itself is saturated at a density of formation of oxygen precipitates exceeding an upper limit value and that it is adversely undesirable to excessively increase a density of formation of oxygen precipitates higher than a density of saturation, because it causes bow or deformation of a substrate easily.

On the other hand, since it is thought that the same initial oxygen concentration in a substrate results in almost the same total volume of oxygen precipitates, it is clear that a higher density of formation of oxygen precipitation (to be more exact, a density of formation in number thereof) makes a structural state of oxygen precipitates obtained finer. In order to obtain an appropriate IG effect at the final stage directly, a density of formation of oxygen precipitates in a substrate is adopted as a control parameter, and a density of oxygen precipitates has been measured in a conventional mass production under observation with an optical microscope on a section of the substrate or with an infrared scattering tomography method. In a boron doped p⁺ CZ substrate (with a resistivity of 0.018Ω·cm or less), however, a size of an oxygen precipitate is in the order of submicron, which necessitates observation at a high magnification in the range of ×500 to ×1000 with an optical microscope. Since observation with an optical microscope at such a high magnification makes it very difficult to be focused correctly, measurement of a density of oxygen precipitates takes a long time. Observation is conducted generally on a substrate surface that has been selectively etched for easy discovery of oxygen precipitates, while if the selective etching results in a rough surface, fine oxygen precipitates are hard to be observed. An infrared scattering tomography method has difficulty in establishing a correlation of measured values between apparatuses.

Moreover, selective etching for making oxygen precipitates observable has also brought a large problem in a conventional method. For example, JIS H0609 (1999) discloses a mixed acid aqueous solution having a volume ratio of hydrofluoric acid, nitric acid, acetic acid and water defined, as a selective etching solution for crystal defect observation, whereas according to a study conducted by the inventors of this invention, it is very difficult to etch a boron doped p⁺ CZ substrate with a resistivity of 0.018Ω·cm or lower so as to make oxygen precipitates observable with this mixed acid aqueous solution. Not only does a transmission electron microscope requires a large amount of labor for preparation of a specimen or the like, but also an observation view field is limited, which makes the microscope not suitable for a counting method of oxygen precipitates in mass production use.

Therefore, because of the above reasons, a density of oxygen precipitates in a p⁺ CZ substrate that has been conventionally disclosed has a high possibility that a density thereof has been counted lower than a actual value despite formation of more oxygen precipitates because of limitation of a resolving power in the above optical observation method and improper conditions of selective etching. As a result, a actual density of formation of oxygen precipitates is exceed in reality, leading to a problem of bow or deformation of substrate with ease.

It is an object of this invention to provide a silicon epitaxial wafer in which, despite that a boron doped p+ CZ substrate with a resistivity of 0.018Ω·cm or lower is used and that sizes of oxygen precipitates are so small that it is difficult to be observed, a state of formation of the oxygen precipitates can be optimized so as to be able to secure a sufficient IG effect and to suppress a problem of bow and deformation of a substrate, and a manufacturing method thereof.

### SUMMARY OF THE INVENTION

A silicon epitaxial wafer of this invention, which has been conducted in order to solve the above problems, is characterized that a silicon epitaxial wafer is manufactured by forming a silicon epitaxial layer on a silicon single crystal substrate (p⁺ CZ substrate) produced by means of a CZ method doped with boron so that a resistivity thereof is 0.018Ω·cm or lower, wherein bulk stacking faults (hereinafter referred to as BSFs) exists in the silicon single crystal substrate constituting the silicon epitaxial wafer at a density in the range of 1×10⁸ cm⁻³ or higher and 3×10⁹ cm⁻³ or lower.

The inventors of this invention have been studied on, in a silicon epitaxial wafer using the above boron doped p⁺ CZ substrate, optimization of a range of condition, in which an IG effect is sufficiently secured and a problem of bow and deformation of a substrate is less likely to be produced, by another parameter different than a density of formation of oxygen precipitates, in light of formation of finer oxygen precipitates makes detection thereof more difficult in a conventional technique. As a result, it was found that bulk stacking faults introduced by annealing of oxygen precipitates has a good correlation with a density of formation of oxygen precipitates and, in a silicon epitaxial wafer using a boron-doped p⁺ CZ substrate with a density of formation of bulk stacking faults in the range of 1×10⁸ cm⁻³ or higher and 3×10⁹ cm⁻³ or lower, the desired characteristic described above can be sufficiently realized, which has led to completion of this invention.

Since, conventionally, a density of formation of fine oxygen precipitates has been unreasonably measured by means of an optical method, the measured values could include many errors, and only for a silicon epitaxial wafer using a boron-doped p⁺ CZ substrate, an adequate numerical range of the density of formation of oxygen precipitates that has been generally accepted cannot necessarily be reliable. In contrast to this, bulk stacking faults adopted by this invention are much easier to be detected under observation with an optical microscope as compared with detection of oxygen precipitates, which reduces a risk of miscounting the faults. Hence, by defining an adequate range of a densitiy of formation of the bulk stacking faults regardless of accuracy in counting of oxygen precipitates, a characteristic can be realized with certainty that an IG effect is secured and, at the same time, bow of a substrate is prevented, even if oxygen precipitates are actually formed considerably small in size.

A bulk stacking fault is a crystal defect introduced by annealing of an oxygen precipitate, and can be observed with an optical microscope even at a magnification in the range of ×50 to ×100 by selective etching of an annealed silicon epitaxial wafer. A density of bulk stacking faults can be obtained by dividing the number of bulk stacking faults observed in a unit area using an optical microscope by an etching stock removal. In a case where, for example, a silicon epitaxial wafer was selectively etched to an etching stock removal of 0.5 μm, and a photograph of 7 cm×9 cm in size was taken with an optical microscope at a magnification of ×1000 with the result of 23 BSFs thereon, a density of bulk stacking faults is calculated as described below:
23×(1000)²/(7×9)/0.5×10⁴=7.3×10⁹ cm⁻³.

If a density of bulk stacking faults is less than 1×10⁸ cm⁻³, a density of formation of oxygen precipitates is insufficient, which enables to secure a sufficient IG effect. On the other hand, if a density of bulk stacking faults exceeds 3×10⁹ cm⁻³, a density of formation of oxygen precipitates becomes excessive, which tends to produce bow or the like in a substrate easily. A density of bulk stacking faults is more desirable in the range of 5×10⁸ cm⁻³ or higher and 2×10⁹ cm⁻³ or lower.

If a resistivity of a substrate is higher than 0.018Ω·cm, a concentration of boron accelerating oxygen precipitation is too small to essentially produce a problem to be otherwise caused by finer oxygen precipitates, and since the number of oxygen precipitation nuclei is also decreased, a density of formation of oxygen precipitates cannot be achieved enough to secure a sufficient IG effect. Base on such circumstances, it is more desirable to set a resistivity of a substrate at a value lower than 0.014Ω·cm. On the other hand, considering that a density of formation of oxygen precipitates is increased to an excessive value, which makes it difficult to produce bow or the like in a substrate, it is desirable that a resistivity of a substrate is set to a value of 0.011Ω·cm or higher.

An initial oxygen concentration in a silicon single crystal substrate is preferable in the range of 6×10¹⁷ cm⁻³ or higher and 10×10¹⁷ cm⁻³ or lower. If the initial oxygen concentration is less than 6×10¹⁷ cm⁻³, a density of formation of oxygen precipitates cannot be sufficiently obtained with certainty, as a result a sufficient IG effect cannot be expected. Contrary to this, if an initial oxygen concentration exceeds 10×10¹⁷ cm⁻³, a density of formation of oxygen precipitates is excessively higher, resulting in a higher possibility of rapid increase in deformation such as bow of a wafer. Note that in this specification, a unit of a oxygen concentration is expressed using standards of JEIDA (an abbreviation of Japanese Electronic Industry Development Association, which has been altered to JEITA, an abbreviation of Japan Electronics and Information Technology Industries Association).

A manufacturing method of a silicon epitaxial wafer of this invention includes: a vapor phase growth step of vapor phase growing of a silicon epitaxial layer on a silicon single crystal substrate, produced by means of a CZ method, and doped with boron so that a resistivity thereof is 0.018Ω·cm or less;

a low temperature annealing step of applying low temperature annealing at a temperature in the range of 450° C. or higher and 750° C. or lower after the vapor growth step to thereby form oxygen precipitation nuclei; and

a medium temperature annealing step of applying medium temperature annealing at a temperature in the range of higher than a temperature in the low temperature annealing and lower than a temperature in vapor phase growth to thereby obtain a density of bulk stacking faults in the silicon single crystal substrate in the range of 1×10⁸ cm⁻³ or higher and 3×10⁹ cm⁻³ or lower,

wherein the steps are conducted in the order described above.

It is more desirable that a resistivity of the substrate is set to a value less than 0.014Ω·cm in order to obtain a density of formation of oxygen precipitate at which an IG effect is sufficiently secured.

By applying the low temperature annealing in the above temperature range after the vapor growth step, oxygen precipitates annihilated or reduced during the vapor phase growth step can be restored to achieve a required density of formation in order to secure an IG effect. Thereafter, by further applying the medium temperature annealing in the range of higher than a temperature in the low temperature annealing and lower than a temperature in vapor phase growth: to be more specific, in the range of 800° C. or higher and lower than 1100° C., oxygen precipitation nuclei can be matured into oxygen precipitates, part of which, at the same time, become bulk stacking faults.

Since a silicon epitaxial wafer of this invention uses a boron doped p⁺ CZ substrate with a low resistivity, oxygen precipitates are formed mainly as fine ones in size of the order that comparatively large ones can be observed barely with an optical microscope at a magnification in the range of ×500 to ×1000 (sizes thereof is assumed 300 nm or less on the average), an accurate density of precipitation nuclei can not be estimated in conclusion. Therefore, in the manufacturing method of this invention, attention is paid to the fact that a density of bulk stacking faults can be easily observed after the medium temperature treatment, and the low temperature annealing and the medium temperature annealing are applied in conditions that a density of bulk stacking faults in the silicon single crystal substrate is in the adequate numerical range. Thereby, the epitaxial wafer of this invention, in which an IG effect is secured and at the same time bow is prevented, can be obtained with certainty.

Since it is difficult, as described above, to directly specify the number of oxygen precipitation in a boron doped p⁺ CZ substrate used in this invention, instead of this, it is necessary that a temperature and a time of low temperature annealing are adequately set, when required, according to a boron concentration so that a density of formation of bulk stacking faults falls in the above range. If a temperature is lower than 450° C., the number of formation of bulk stacking faults (or oxygen precipitation nuclei) decreases extremely, and to the contrary if a temperature exceeds 750° C., the number of formation of bulk stacking faults (or oxygen precipitation nuclei) becomes insufficient because of a super-saturation degree of interstitial oxygen is excessively low. Therefore, a temperature of the low temperature annealing is set in the range of 450° C. or higher and 750° C. or lower.

### BRIEF DESCRIPTION OF THE DRAWINGS

FIG. 1 is a schematic view showing a silicon epitaxial wafer of this invention.

FIG. 2 is process views describing a manufacturing method of a silicon epitaxial wafer of this invention.

FIG. 3 is a graph showing a relationship between a density of bulk stacking faults and a density of oxygen precipitates.

FIG. 4 is a photograph of bulk stacking faults and oxygen precipitates taken with an optical microscope at a magnification of ×1000.

### DETAILED DESCRIPTION OF THE PREFERRED EMBODIEMENT

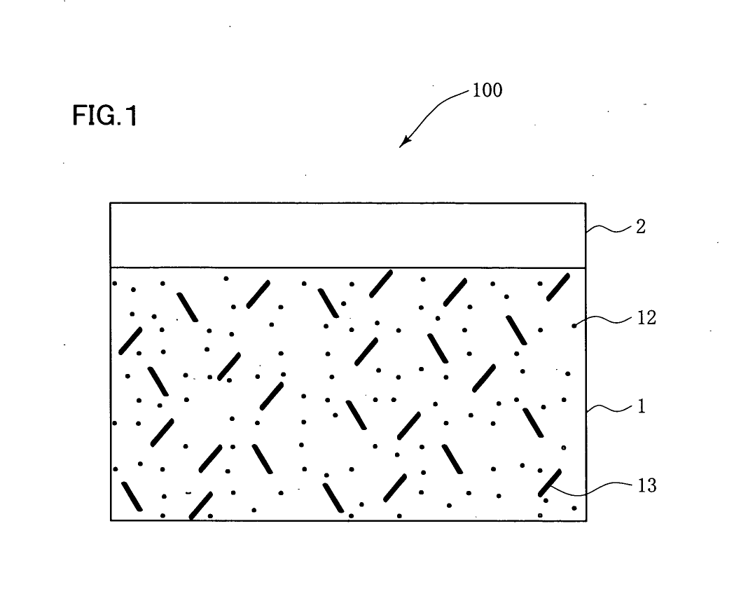

Description will be described below of the best mode for carrying out this invention using the accompanying drawings. In FIG. 1, there is shown a schematic view of a silicon epitaxial wafer 100 of this invention. A silicon epitaxial wafer 100 of this invention is manufactured by vapor phase growing of a silicon epitaxial layer 2 at a temperature of 1100° C. or higher on a silicon single crystal substrate produced by means of a CZ method doped with boron so that a resistivity thereof is in the range of 0.009Ω·cm or higher and 0.018Ω·cm or lower. Low temperature annealing in the range of 450° C. or higher and 750° C. or lower is applied to the silicon epitaxial wafer 100 and medium temperature annealing in the range of a temperature in the low temperature annealing or higher and a temperature in the vapor phase growth or lower is further applied to the silicon epitaxial wafer 100 to thereby produce oxygen precipitates 12 and bulk stacking faults 13 at a density in the range of 1×10⁸ cm⁻³ or higher and 3×10⁹ cm⁻³ or lower in the silicon single crystal substrate 1. The oxygen precipitates 12 are very fine and produced at a density of about 10 times a density of BSF 13 to exert an IG effect.

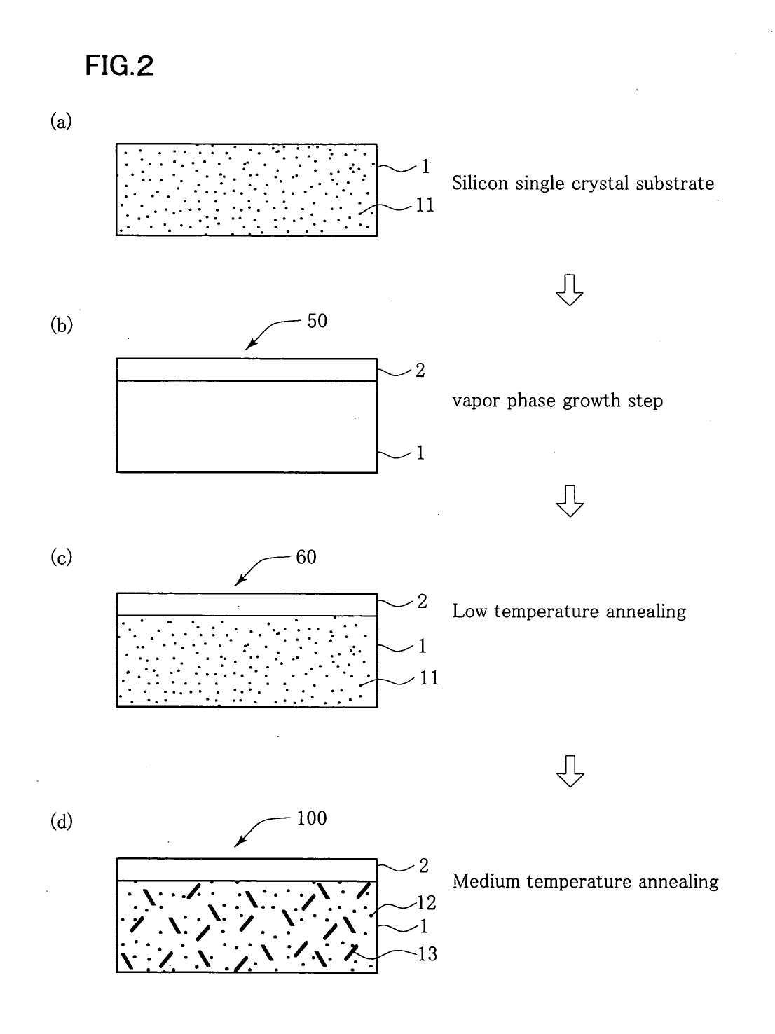

An interstitial oxygen concentration in the silicon single crystal substrate 1 is controlled in the range of 6×10¹⁷ cm⁻³ or higher and 10×10¹⁷ cm⁻³ or lower. If an interstitial oxygen concentration does not reach 6×10¹⁷ cm⁻³, oxygen precipitation nuclei 11 (FIG. 2) with a sufficient density are less likely to be produced in the silicon single crystal substrate 1, for example, in low temperature annealing in the range of 450° C. or higher and 750° C. or lower for a short time less than 3 hr after the vapor phase growth, and oxygen precipitates 12 are also less likely to be produced at a sufficient concentration in medium temperature annealing subsequent to the low temperature annealing, and therefore a sufficient gettering effect can not expected. Contrary thereto, if an initial oxygen concentration exceeds 10×10¹⁷ cm⁻³, oxygen precipitates 12 are excessively produced in the medium temperature annealing because of a great amount of oxygen precipitation nucleus produced in the low temperature annealing, resulting in a higher possibility of rapid increase in deformation of the wafer. Note that it is preferable to control a density of oxygen precipitates 12 to less than 1×10¹¹ cm⁻³ in order to suppress deformation of the wafer.

In FIG. 2, there are shown process views describing a manufacturing method of a silicon epitaxial wafer 100 of this invention. First of all, prepared is a p⁺ CZ silicon single crystal substrate 1 (hereinafter referred simply to as a substrate 1), doped with boron having a resistivity of 0.009Ω·cm or higher and 0.018Ω·cm or lower and adjusted so as to have an initial oxygen concentration in the range of 6×10¹⁷ cm⁻³ or higher and 10×10¹⁷ cm⁻³ or lower (FIG. 2 step (a)). In the substrate 1, there are oxygen precipitation nuclei 11 formed during cooling down to room temperature from solidification of a silicon single crystal in the crystal pulling step.

Then, a vapor phase growth step is conducted in which a silicon epitaxial layer 2 is vapor phase grown on the substrate 1 at a temperature of 1100° C. or higher to thereby obtain a silicon epitaxial wafer 50 (FIG. 2 step (b)). Since the vapor phase growth step is conducted at a high temperature of 1100° C. or higher, almost all of the oxygen precipitation nuclei 11 in the substrate 1 formed in the crystal pulling step is in a solution state.

The silicon epitaxial wafer 50 is placed into a annealing furnace not shown after the vapor phase growth step and the low temperature annealing in the range of 450° C. or higher and 750° C. or lower is applied for a given time in an oxidative atmosphere to again form oxygen precipitation nuclei 11 in the substrate 1 and thereby a silicon epitaxial wafer 60 is formed (FIG. 2, step (c)). The oxidative atmosphere is an atmosphere composed of, for example, dry oxygen diluted with an inert gas such as nitrogen, but may also be an atmosphere of 100% dry oxygen. If the low temperature annealing is conducted at a temperature lower than 450° C., diffusion of interstitial oxygen extremely slows, which makes oxygen precipitation nuclei 11 hard to be formed. To the contrary, if a temperature of the low temperature annealing is higher than 750° C., oxygen precipitation nuclei 11 are also hard to be formed since a supersaturation degree of interstitial oxygen is lowered.

The oxygen precipitation nuclei 11 is matured into oxygen precipitates 12 by further applying the medium annealing in the range of 800° C. or higher and lower than 1100° C. (FIG. 2(d)) and at the same time, part of the oxygen precipitates 12 is altered to BSFs 13 to thereby obtain a silicon epitaxial wafer 100. Temperatures and time lengths of the low temperature annealing and the medium temperature annealing are adjusted so that a density of BSFs to be observed is in the range of 1×10⁸ cm⁻³ or higher and 3×10⁹ cm⁻³ or lower.

### EXAMPLE 1

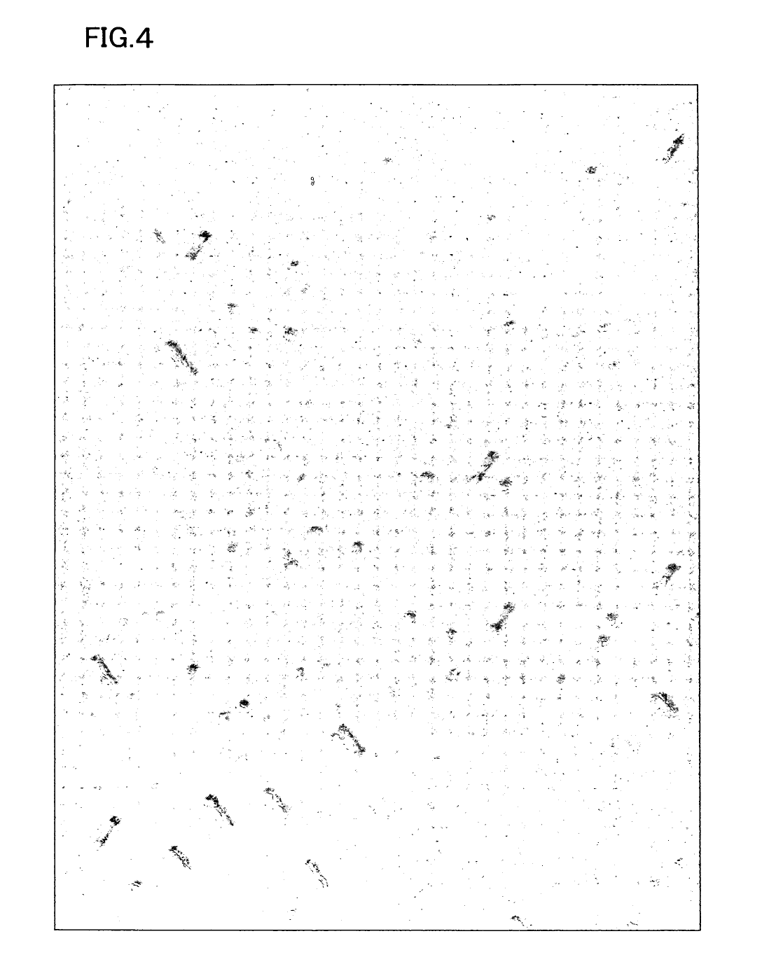

Further detailed description will be given below of this invention with examples. Note that an initial oxygen concentration in a silicon single crystal substrate 1 described in the example is usually expressed as a conversion of a measured value by means of an inert gas fusion method, based on a correlation between a Fourier transform infrared spectroscopy and an inert gas fusion method, obtained using a substrate with an ordinary resistivity (in the range of 1 to 20Ω·cm). A density of oxygen precipitation nuclei and a density of BSFs are measured in the following way: the medium temperature annealing is further applied to the silicon epitaxial wafer 60 in which oxygen precipitation nuclei 11 have been produced to thereby mature the nuclei to oxygen precipitates 12 and BSFs 13 and thereafter, the silicon epitaxial wafer 60 is selectively etched using an etching solution including hydrofluoric acid (with a concentration in the range of 49 to 50 wt %): nitric acid (with a concentration in the range of 60 to 62 wt %): acetic acid (with a concentration in the range of 99 to 100 wt %): water=1:15:6:6 (in volume ratio) and then measurement is conducted using an optical microscope with a magnification of ×1000. Use of this etching solution with the composition enables to observe not only BSFs 13 but also fine oxygen precipitates 12 clearly, as compared with the etching solution disclosed in the JIS. In FIG. 4, there is shown an image obtained with an optical microscope as an example, wherein a BSF 13 appears in a comparatively narrow and long rod shape, while an oxygen precipitate 12 appears fine in a dispersed dots state.

First of all, a boron doped silicon single crystal substrate 1 with a resistivity of 0.012Ω·cm and an initial oxygen concentration of 6.8×10¹⁷ cm⁻³ (13.6 ppma) is prepared and a silicon epitaxial layer 2 with a resistivity of 20Ω·cm and a thickness of 5 μm is vapor phase grown on the (100) main surface of the substrate 1 at a temperature of 1100° C. to obtain a silicon epitaxial wafer 50.

Then, low temperature annealing for producing oxygen precipitation nuclei is conducted on the silicon epitaxial wafer 50 at a temperature of 650° C. for 1 hr, in an oxidative atmosphere composed of 3% oxygen and 97% nitrogen, so as to obtain the silicon epitaxial wafer 60. Thereafter, medium temperature annealing was applied in conditions of 800° C. for 4 hr and 1000° C. for 16 hr in the order to grow oxygen precipitates 12 and BSFs 13, and a density of oxygen precipitation nuclei and a density of BSFs in the substrate 1 constituting the obtained silicon epitaxial wafer 100 were evaluated, so as to obtain the results that the density of oxygen precipitation was 1.3×10¹⁰ cm⁻³ and the density of BSFs was 1.6×10⁹ cm⁻³.

Note that a silicon epitaxial wafer was, for comparison, obtained by applying vapor phase growth and annealing in the same conditions as in Example 1 except the use of a boron doped silicon single crystal substrate 1 with a resistivity of 0.016Ω·cm and an initial oxygen concentration of 6.0×10¹⁷ cm⁻³(12.0 ppma) without low temperature annealing applied, with the result that formation of neither oxygen precipitates 12 nor BSFs 13 could not be recognized.

### EXAMPLE 2

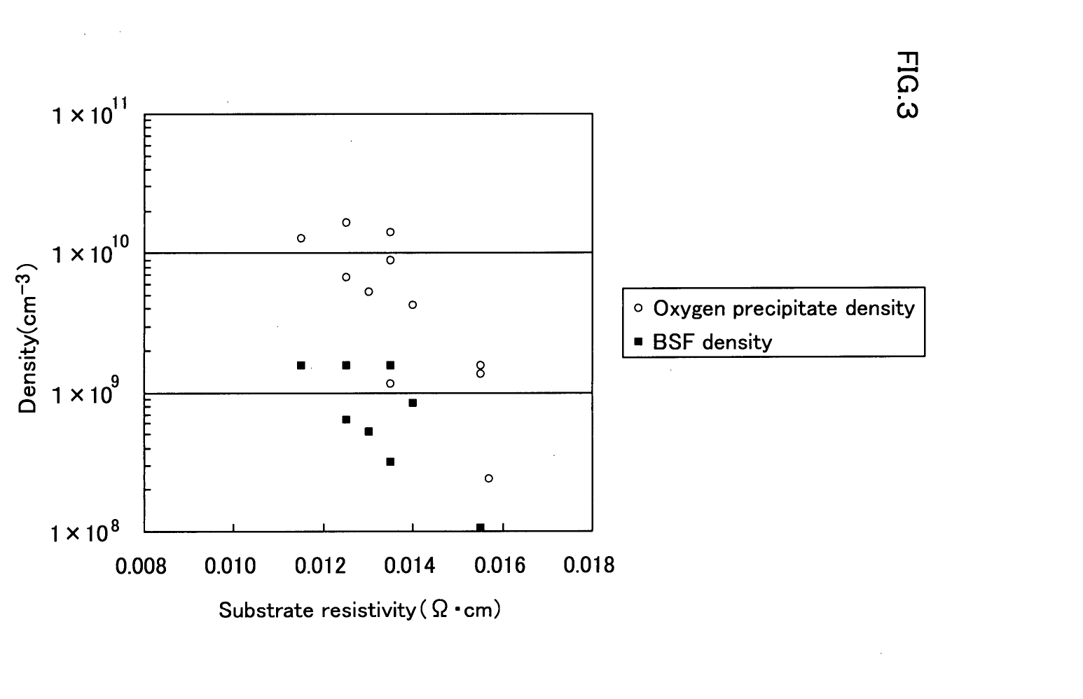

In FIG. 3, there is shown a relationship in densities of formation between oxygen precipitates 12 and BSFs 13 in a case where low temperature annealing in conditions of 650° C. for 1 hr and medium temperature annealing in conditions of 800° C. for 4 hr and 1000° C. for 16 hr were applied in this order to a silicon epitaxial wafer 50 manufactured as described above using p⁺ CZ substrates with various resistivities set. Both clearly has a positive correlation and it is recognized that a density of oxygen precipitates 12 has a value approximately 10 times a density of BSFs 13 in the substrate resistivity range of 0.011Ω·cm or higher and 0.018Ω·cm or lower. Note that the density of oxygen precipitates correctly measured for the first time by using the etching solution described above. It is also recognized that by using a silicon single crystal substrate with a resistivity of 0.014Ω·cm or lower, a density of oxygen precipitates 12 can be set to a density of 1×10⁹ cm⁻³ or higher so as to assure a sufficient IG effect (wherein a density of BSFs 13 was 3×10⁸ cm⁻³ or higher at this measurement).

1. A silicon epitaxial wafer, manufactured by forming a silicon epitaxial layer on a silicon single crystal substrate produced by means of a CZ method doped with boron so that a resistivity thereof is 0.018Ω·cm or lower, wherein bulk stacking faults exists in the silicon single crystal substrate constituting the silicon epitaxial wafer at a density in the range of 1×1⁸ cm⁻³ or higher and 3×10⁹ cm⁻³ or lower.

2. The silicon epitaxial wafer according to claim 1, wherein a resistivity of the silicon single crystal substrate is lower than 0.014Ω·cm

3. The silicon epitaxial wafer according to claim 1, wherein a resistivity of the silicon single crystal substrate is lower than 0.011Ω·cm or higher.

4. The silicon epitaxial wafer according to claim 1, wherein an initial oxygen concentration in the silicon single crystal substrate is in the range of 6×10¹⁷ cm⁻³ or higher and 10×10¹⁷ cm⁻³ or lower.

5. A manufacturing method of a silicon epitaxial wafer comprising: a vapor phase growth step of vapor phase growing of a silicon epitaxial layer on a silicon single crystal substrate, produced by means of a CZ method, and doped with boron so that a resistivity thereof is 0.018Ω·cm or lower;
a low temperature annealing step of applying low temperature annealing at a temperature in the range of 450° C. or higher and 750° C. or lower after the vapor phase growth step to thereby form oxygen precipitation nuclei; and
a medium temperature annealing step of applying medium temperature annealing at a temperature in the range of higher than a temperature in the low temperature annealing and lower than a temperature in the vapor phase growth to thereby obtain a density of bulk stacking faults in the silicon single crystal substrate in the range of 1×10⁸ cm⁻³ or higher and 3×10⁹ cm⁻³ or lower, wherein these steps are conducted in the order described above.

6. The manufacturing method of a silicon epitaxial wafer according to claim 5, wherein a resistivity of the silicon single crystal substrate is lower than 0.014Ω·cm

7. The silicon epitaxial wafer according to claim 2, wherein a resistivity of the silicon single crystal substrate is lower than 0.011Ω·cm or higher.
